(19) United States
(12) Patent Application Publication
(10) Pub. No.: US 2016/0053382 A1
(43) Pub. Date: Feb. 25, 2016

(54) ETCHANT COMPOSITION

(71) Applicants: LG DISPLAY CO., LTD., Seoul (KR); ENF Technology Co., Ltd., Seoul (KR)

(72) Inventors: Kang Rae JUNG, Paju-si (KR); Hyo Seop SHIN, Seoul (KR)

(21) Appl. No.: 14/709,110

(22) Filed: May 11, 2015

(30) Foreign Application Priority Data
Aug. 25, 2014 (KR) 10-2014-0111020

(51) Int. Cl. C23F 1/18; H01L 29/786; H01L 29/66

(52) U.S. Cl. CPC C23F 1/18; H01L 29/66742; H01L 29/7869

(57) ABSTRACT

An etchant composition is disclosed which includes hydrogen peroxide, an etch inhibitor, a chelating agent, an etch additive, an oxide semiconductor protective agent, and a pH regulator. The oxide semiconductor protective agent is included in the etchant composition by about 0.1˜3.0 wt % based on the total weight of the etchant composition. Such an etchant composition according to the present disclosure does not include any fluoride base compound and has a high pH value of about 3.5˜6. As such, the etchant composition allows an oxide semiconductor to not be etched in an etch process of copper and a molybdenum alloy. Therefore, the etchant composition can minimize faults that can be easily generated during the etching process.

The present application claims priority under 35 U.S.C. §119(a) of Korean Patent Application No. 10-2014-0111020 filed on Aug. 25, 2014 which is hereby incorporated by reference in its entirety.

### BACKGROUND OF THE INVENTION

1. Field of the Disclosure

The present application relates to an etchant composition. More particularly, the application relates to an etchant composition used to etch copper and a copper-molybdenum alloy which are used as electrodes of display devices such as an OLED (organic light emitting display) device, a TFT-LCD (thin film transistor liquid crystal display) device or others.

2. Discussion of the Related Art

In general, the TFT-LCD device includes a liquid crystal panel which is configured with a thin film transistor substrate, a color filter substrate and a liquid crystal layer interposed between the two substrates. The liquid crystal layer is sealed off by a sealant which is printed on edges of the two substrates. Such a liquid crystal panel is a non-luminous element. As such, a back light unit must be disposed on the rear (or outer) surface of the thin film transistor substrate.

Meanwhile, the OLED device includes a thin film transistor substrate and organic light emitting elements. The organic light emitting element includes a first electrode, an organic emission layer and a second electrode. The first electrode is connected to a thin film transistor on the thin film transistor substrate.

Wirings are formed on each of the thin film transistor substrates for the TFT-LCD device and the OLED device. The wirings are used for transferring signals to the liquid crystal layer or the organic light emitting elements. The wirings on the thin film transistor substrate include a gate wiring and a data wiring.

The gate wiring includes gate lines and gate electrodes of the thin film transistors. The gate line is used to transfer a gate signal. The data wiring includes data lines and data electrodes of the thin film transistors. The data line is used to transfer a data signal. The data electrode of the thin film transistor is configured with a drain electrode and a source electrode of the thin film transistor.

Such wirings can be formed in a single metal layer or a single metal alloy layer. However, in order to make up for disadvantages of metals and metal alloys and obtain desired physical properties, most wirings are formed in a multi-layer structure. It is preferable for the wirings to use copper as a low resistance metal. In this case, the metal wiring can be configured with a copper layer and a molybdenum alloy layer which is formed under the copper layer and used as a diffusion barrier.

The metal wiring is formed by patterning the metal layers through an etch process. The etch process for the formation of the metal wiring mainly uses a wet etching method which secures high productivity. Current etchant compositions for etching the copper layer and the molybdenum alloy layer include a fluorine-based compound. Such etchant compositions have a low pH value of about 2˜3.

The copper layer and the molybdenum alloy layer are etched by one of the above-mentioned etchant compositions in order to form a source electrode and a drain electrode. In this case, the fluorine-based compound and the low pH force an oxide semiconductor (InGaZnO) layer disposed under the source and drain electrodes to be etched together with the copper layer and the molybdenum alloy layer.

### SUMMARY OF THE INVENTION

Accordingly, embodiments of the present application are directed to an etchant composition that substantially obviates one or more of the problems due to the limitations and disadvantages of the related art.

An advantage of the present invention is to provide an etchant composition which is adapted to minimize generable faults in an etch process by preventing any etching of an oxide semiconductor when copper and a molybdenum alloy are wet-etched.

Additional features and advantages of the embodiments will be set forth in the description which follows, and in part will be apparent from the description, or may be learned by practice of the embodiments. The advantages of the embodiments will be realized and attained by the structure particularly pointed out in the written description and claims hereof as well as the appended drawings.

According to a general aspect of the present embodiment, an etchant composition includes: hydrogen peroxide; an etch inhibitor; a chelating agent; an etch additive; an oxide semiconductor protective agent; and a pH regulator. The oxide semiconductor protective agent is included in the etchant composition by about 0.1˜3.0 wt % based on the total weight of the etchant composition. Such an etchant composition according to the present disclosure does not include any fluoride base compound and has a high pH value of about 3.5˜6. As such, the etchant composition allows an oxide semiconductor to not be etched in an etch process of copper and a molybdenum alloy.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with the embodiments. It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the embodiments and are incorporated herein and constitute a part of this application, illustrate embodiment(s) of the present disclosure and together with the description serve to explain the disclosure. In the drawings:

FIG. 1 is a cross-sectional view showing a display device according to an embodiment of the present disclosure;

FIG. 2 is a scanning electron microscope image which shows side surfaces (or cross-sections) of a sample plate for checking the thickness variation of an exposed oxide semiconductor layer when copper and molybdenum alloy layers are etched by an etchant composition according to an embodiment of the present disclosure;

FIG. 3 is a scanning electron microscope image which shows an upper surface of the sample plate for checking the thickness variation of an exposed oxide semiconductor layer when copper and molybdenum alloy layers are etched by an etchant composition according to an embodiment of the present disclosure;

FIG. 4 is a scanning electron microscope image showing a state of an oxide semiconductor layer which is etched by an etchant composition according to an embodiment of the present disclosure; and

FIG. 5 is a scanning electron microscope image showing a state of an oxide semiconductor layer which is etched by an etchant composition according to a comparative example.

### DETAILED DESCRIPTION OF THE EMBODIMENTS

Reference will now be made in detail to embodiments of the present disclosure, examples of which are illustrated in the accompanying drawings. These embodiments introduced hereinafter are provided as examples in order to convey their spirits to the ordinary skilled person in the art. Therefore, these embodiments might be embodied in a different shape, so are not limited to these embodiments described here. In the drawings, the size, thickness and so on of a device can be exaggerated for convenience of explanation. Wherever possible, the same reference numbers will be used throughout this disclosure including the drawings to refer to the same or like parts.

An etchant composition according to an embodiment of the present disclosure includes hydrogen peroxide, an etch inhibitor, a chelating agent, an etch additive, an oxide semiconductor protective agent and a pH regulator. The etchant composition can further include water allowing the etchant composition to become 100 wt %. Also, the etchant composition according to an embodiment of the present disclosure can be used in a fabrication procedure of a display device.

The etchant composition according to an embodiment of the present disclosure can simultaneously etch copper and a molybdenum alloy. In other words, the etchant composition can etch double metal layers which are formed from copper and the molybdenum alloy.

The molybdenum alloy can be prepared by alloying molybdenum and one of various metals. For example, the molybdenum alloy can be prepared by alloying molybdenum with one of titanium Ti, tantalum Ta, chromium Cr, neodymium Nd, nickel Ni, indium In and tin Sn. Preferably, the molybdenum alloy is a molybdenum-titanium alloy. The molybdenum-titanium alloy can be used to increase the adhesive force between a copper layer and an oxide semiconductor layer formed under the copper layer.

The hydrogen peroxide can be used as a main oxidizer for copper and the molybdenum alloy. Also, the hydrogen peroxide is preferably contained in the etchant composition by about 5˜40 wt % based on the total weight of the etchant composition.

If the content of the hydrogen peroxide is below 5 wt %, an oxidizing power for copper and the molybdenum alloy is not enough. As such, copper and the molybdenum alloy can be properly etched. When the content of the hydrogen peroxide is about 40 wt %, an etching speed of copper and the molybdenum alloy becomes very fast. Due to this, it can be difficult to control the etch process.

The etch inhibitor controls the etching speed of copper and the molybdenum alloy and allows an etch profile with a proper taper angle to be obtained. Preferably, the etch inhibitor is contained in the etchant composition by about 0.1˜5 wt % based on the total weight of the etchant composition.

If the content of the etch inhibitor is below 0.1 wt %, the control ability of the etch inhibitor for the taper angle can deteriorate. When the content of the etch inhibitor is above 5 wt %, the etching speed of copper and the molybdenum alloy can become very slow.

Such an etch inhibitor can be a heterocyclic compound which has the carbon number of 1˜10 and includes at least one heteroatom selected from oxygen, sulfur and nitrogen. In detail, the etch inhibitor can become one of aromatic heterocyclic compounds and aliphatic heterocyclic compounds. The aromatic heterocyclic compounds include furan, thiophene, pyrrol, oxazole, imidazole, pyrazole, triazole, tetrazole, benzofuran, benzothiophene, indole, benzimidazole, benzpyrazole, aminotetrazole, methyltetrazole, tolutriazole, hydro tolutriazole, hydroxyl tolutriazole and so on. The aliphatic heterocyclic compounds include piperazine, methylpiperazine, hydroxylethylpiperazine, pyrrolidine, alloxan and so on. One or at least two selected from the above-mentioned materials can be used as the etch inhibitor.

The chelating agent is chelated with ions, which are generated at the etch of copper and the molybdenum alloy, and forces the ions to be not activated. As such, a decomposition reaction of the hydrogen peroxide included into the etchant composition can be suppressed. The ions can include copper ions and molybdenum alloy ions. As the ions are not activated in the etch process, heat generation and explosion easily caused by a promoted decomposition reaction of the hydrogen peroxide can be prevented.

The chelating agent is preferably contained in the etchant composition by about 0.1˜5 wt % based on the total weight of the etchant composition. If the chelating agent is below 0.1 wt %, the ability to control the decomposition reaction of the hydrogen peroxide can deteriorate because the quantity of metal ions to be non-activated is very small. On the contrary, when the chelating agent is above 5 wt %, it is difficult to obtain an active non-activating the metal ions. In other words, it is difficult to effectively non-activate the metal.

The chelating agent can be a compound which includes all of an amino group and carboxyl group. For example, the chelating agent can be one of iminodiacetic acid, nitrilotriacetic acid, ethylenediaminetetraacetic acid, diethylenetrinitrilpantaacetic acid, aminotri(methylenephosphonic acid), 1-hydroxyethane(1,1-diylbis(phosphonic acid)), ethylenediaminetetra(methylenephosphonic acid), diethylenetriaminepanta(methylenephosphonic acid), sarcocine, alanine, glutamic acid, aminobutyric acid, glycine and so on.

The etch additive can adjust the etching speed of copper and the molybdenum alloy. Preferably, the etch additive is contained in the etchant composition by about 0.1˜5 wt % based on the total weight of the etchant composition.

If the etch additive is below 0.1 wt %, the etching speed of copper and the molybdenum alloy can become very slow. On the contrary, when the etch additive is above 5 wt %, the etching speed of copper and the molybdenum alloy becomes fast. In this case, it is difficult to control the etch process.

The etch additive can be either a compound including an organic acid, an inorganic acid, nitrogen and sulfur or another compound including an organic acid salt, an inorganic acid salt, nitrogen and sulfur. The organic acid can be one of water-soluble organic acids. The water-soluble organic acids include acetic acid, formic acid, butanoic acid, citric acid, glycolic acid, oxalic acid, malonic acid, pentanoic acid, propionic acid, tartaric acid, gluconic acid, glucosan, succinic acid and so on. The etch additive can include at least one of the above-mentioned water-soluble organic acids. The inorganic acid can be one of nitric acid, sulfuric acid, phosphoric acid, hydrochloric acid, hypochlorous acid, permanganic acid and mixtures thereof.

The oxide semiconductor protective agent prevents the etch of an oxide semiconductor which is exposed in the etch process of copper and the molybdenum alloy. The oxide semiconductor can be one of IGZO (indium gallium zinc oxide), IZO (indium zinc oxide), IGO (indium gallium oxide), In₂O₃ and combinations thereof.

Preferably, the oxide semiconductor protective agent is contained into the etchant composition by about 0.1˜3 wt % based on the total weight of the etchant composition. If the content of the oxide semiconductor protective agent is below 0.1% wt %, the oxide semiconductor can be etched by the etchant composition. On the contrary, when the content of the oxide semiconductor protective agent is above 3 wt %, the etching speed of copper and the molybdenum alloy can become slower. Such an oxide semiconductor protective agent can be a compound including an amine group. In detail, the oxide semiconductor protective agent can be a compound including an amine group and one of alcohol, carboxylic acid and so on. For example, the oxide semiconductor protective agent can be one of monoethanolamine and hexamethylenetetramine.

The pH regulator can control the etchant composition to maintain a pH range of about 3.5˜6. If the pH of the etchant composition is below 3.5, the oxide semiconductor can be etched. On the contrary, when the pH of the etchant composition is above 6.0, copper and the molybdenum alloy cannot be properly etched. To this end, it is preferable for the etchant composition to contain the pH regulator by about 0.1˜3.0 wt % based on the total weight of the etchant composition.

If the content of the pH regulator is below 0.1 wt %, the etch action of the hydrogen peroxide included in the etchant composition can be shortly activated. On the contrary, when the content of the pH regulator is above 3.0 wt %, the pH of the etchant composition steeply increases and the activation of the hydrogen peroxide is lowered. Due to this, the etching speed of copper and the molybdenum alloy and the etching uniformity can deteriorate. Such a pH regulator can be an inorganic alkali. For example, the pH regulator can include at least one of sodium carbonate, sodium hydroxide, potassium hydroxide and ammonia.

The water included into the etchant composition is not specified, but it is preferable for the etchant composition to use deionized water. Preferably, deionized water with a resistivity of at least 18MΩ/cm is included in the etchant composition. The resistivity means a degree which removes ions from water. As the deionized water is included in the etchant composition, the quantity of impurities generated in the etch process can be reduced.

Preferably, the etchant composition according to the present disclosure can include about 5˜40 wt % of the hydrogen peroxide, about 0.1˜5 wt % of the etch inhibitor, about 0.1˜5.0 wt % of the etch additive, about 0.1˜3.0 wt % of the oxide semiconductor protective agent, about 0.1˜3.0 wt % of the pH regulator and water corresponding to the rest of the wt %, when the total weight of the etchant has 100 wt %. Also, the etchant composition can further include an ordinary additive with the exception of the above-mentioned components. For example, the etchant composition can further include a surfactant. As an example of the surfactant, any one of surfactants well known to an ordinary skilled person in the art can be used. Such an additive can enhance the etch performance of the etchant composition.

Such an etchant composition according to the present disclosure etches copper and molybdenum alloy films, which may be used as electrodes of LCD and OLED devices and so on while minimizing the etch of a film under the copper and the molybdenum alloy films. As such, faults of elements can be prevented. The film under the copper and molybdenum alloy films can be an oxide semiconductor layer.

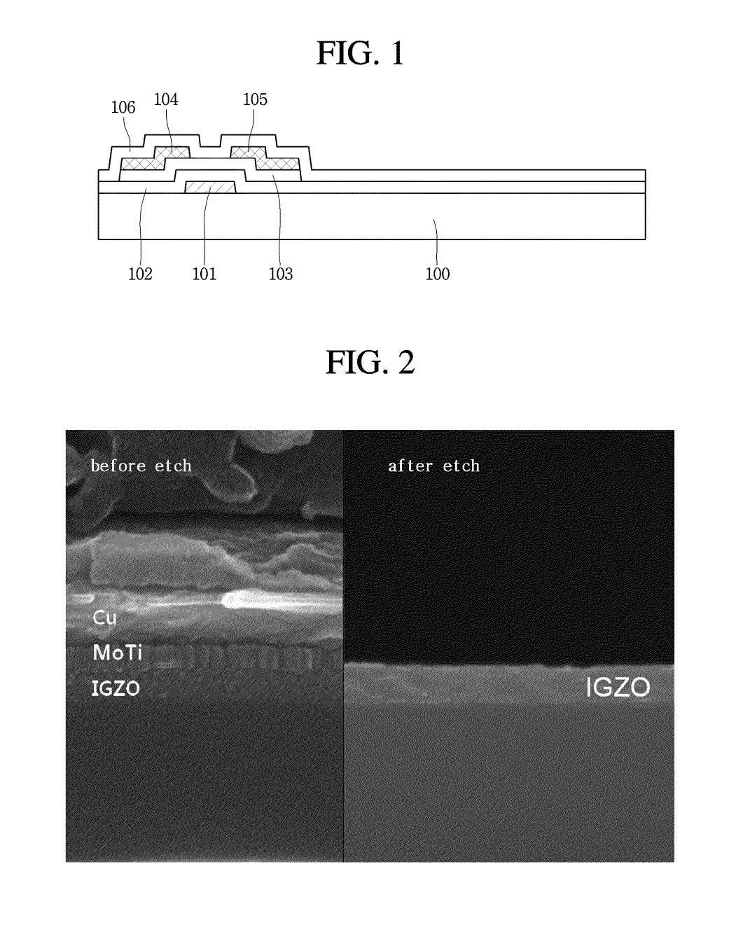

Subsequently, a display device fabrication method using an etchant composition in accordance with the present disclosure will now be described in detail. FIG. 1 is a cross-sectional view illustrating a display device fabrication method according to the present disclosure. Referring to FIG. 1, a substrate 100 is prepared. A thin film transistor is formed on the substrate 100. The thin film transistor includes a gate electrode 101, a gate insulation film 102, a semiconductor layer 103, a source electrode 104 and a drain electrode 105.

In detail, the gate electrode 101 is formed on the substrate 100. In order to form the gate electrode 101, a metal material layer is formed on the substrate 100. The metal material layer can be formed from one of various materials. For example, the metal material layer can be formed from one of copper (Cu), silver (Ag), aluminum (Al), chromium (Cr), titanium (Ti), tantalum (Ta) and alloys thereof.

Thereafter, a photoresist layer is formed on the metal material layer. A photoresist pattern is formed by performing exposure and development processes using a mask which includes a transmission portion and a blocking portion. Also, the gate electrode 101 is formed by etching the metal material layer using the photoresist pattern as a mask.

The gate insulation film 102 is formed on the entire surface of the substrate 100 provided with the gate electrode 101. The gate insulation film 102 is used to protect the gate electrode 101.

The semiconductor layer 103 is formed on the gate insulation film 102. The semiconductor layer 103 can be formed from an oxide semiconductor material. For example, the semiconductor layer 103 can be formed from one of IGZO (indium gallium zinc oxide), IZO (indium zinc oxide), IGO (indium gallium oxide), In₂O₃ and combinations thereof.

The oxide semiconductor thin film transistor has a higher mobility than that of an amorphous silicon (a-Si) thin film transistor. Also, the oxide semiconductor thin film transistor has a simplified fabrication procedure, and lower the fabrication cost compared with a poly-silicon (poly-Si) thin film transistor. Although it is not shown in the drawing, a non-conductivity protective layer can be formed on the oxide semiconductor layer in order to maintain electrical properties of the oxide semiconductor layer. The non-conductivity protective layer can become an etching stopper.

The source electrode 104 and the drain electrode 105 are formed on the semiconductor layer 103. To this end, an electrode material layer (or a source/drain electrode material layer) is formed on the substrate 100 provided with the semiconductor layer 103. The electrode material layer can be formed from a metal material. Alternatively, the electrode material layer can be formed in a double layered structure. In detail, a first electrode material layer can be formed on the semiconductor layer 103 and a second electrode material layer can be formed on the first electrode material layer.

The first electrode material layer can be formed from a molybdenum alloy. The second electrode material layer can be formed from copper Cu. Copper has an advantage of very low resistance. The molybdenum alloy prevents any diffusion of copper and enhances an adhesive force of copper.

The source electrode 104 and the drain electrode 105 can be formed by etching the first electrode material layer and the second electrode material layer through a photoresist procedure. In this time, the etchant composition according to the present disclosure can be used to etch the first electrode material layer and the second electrode material layer.

An etchant composition including a fluoride based compound can be used to etch the source/drain electrode material layer. In this case, the etchant composition has a low pH of about 2˜3. When the source/drain electrode material layer including the copper layer and the molybdenum alloy layer is etched by the etchant composition including the fluoride based compound, the fluoride based compound and the low pH force etch not only the source/drain electrode material layer but also the oxide semiconductor layer formed under the source/drain electrode material layers to be etched.

Meanwhile, the etchant composition according to the present disclosure does not include any fluoride base compound and has a pH value of about 3.5˜6. As such, only the source/drain electrode material layer including the copper layer and the molybdenum alloy layer can be etched by the etchant composition according to the present disclosure. In other words, the etchant composition according to the present disclosure can etch only the source/drain electrode material layer, which includes the copper layer (i.e., the second electrode material layer) and the molybdenum alloy layer (i.e., the first electrode material layer), without etching the semiconductor layer 103.

In this manner, the etchant composition according to the present disclosure does not etch the semiconductor layer formed from the oxide semiconductor. As such, a formation process of a non-conductivity protective layer used to protect the semiconductor layer 103 from the etching solution which is used to etch the source/drain electrode material layer can be omitted. Therefore, the etchant composition according to the present disclosure can simplify the display device fabrication procedure.

The etchant composition according to the present disclosure includes about 5˜40 wt % of the hydrogen peroxide, about 0.1˜5 wt % of the etch inhibitor, about 0.1˜5.0 wt % of the etch additive, about 0.1˜3.0 wt % of the oxide semiconductor protective agent, about 0.1˜3.0 wt % of the pH regulator and water corresponding to the rest of the wt %, when the total weight of the etchant is 100 wt %.

A passivation film 106 is formed on the entire surface of the substrate 100 provided with the source electrode 104 and the drain electrode 105 which are prepared through the etch process using the etchant composition according to the present disclosure. The passivation film 106 can be used to protect the source electrode 104 and the drain electrode 105.

The etchant composition according to the present disclosure does not include any fluoride base compound and has a pH value of about 3.5˜6. As such, when the source/drain electrode material layer including the copper layer and the molybdenum alloy layer is etched by the etchant composition according to the present disclosure, the etch of the semiconductor layer 103 formed under the source/drain electrode material layer can be prevented. Moreover, since a non-conductivity protective layer formed on the semiconductor layer 103 is removed, the display device fabrication procedure can be simplified.

Hereinafter, etchant compositions according to embodiments of the present disclosure will now be described in detail in such a manner as to be compared with those of comparative examples.

The embodiments and the comparative examples below are provided as examples of the present disclosure, but they do not limit the present disclosure. The present embodiments and the comparative examples might be embodied and modified in a variety of shapes.

### First Through Fourth Embodiments and First Through Third Comparative Examples

The etchant compositions according to the first through fourth present embodiments and the first through third comparative examples are mixed and fabricated based on components and contents in the following table 1.

TABLE 1

| | | | | | | | | Oxide | | | | Fluoride | | |
|---|---|---|---|---|---|---|---|---|---|---|---|---|---|---|
| | Hydrogen | Etch | | Chelating | | Etch | | semiconductor | | | | based | | |
| | peroxide | inhibitor | | agent | | additive | | protective agent | | pH regulator | | compound | | water |
| Items | [wt %] | [wt %] | | [wt %] | | [wt %] | | [wt %] | | [wt %] | | [wt %] | | [wt %] |
| PEM1 | 20 | ATZ | 1.0 | IDA | 2.0 | SHS | 1.0 | MEA | 1.0 | NaOH | 1.0 | — | — | 75.0 |
| PEM2 | 20 | ATZ | 1.0 | IDA | 2.0 | SHS | 1.0 | MEA | 1.0 | NaOH | 2.0 | — | — | 74.0 |
| PEM3 | 20 | ATZ | 1.0 | IDA | 2.0 | SHS | 1.0 | HMTA | 1.0 | NaOH | 1.0 | — | — | 75.0 |
| PEM4 | 20 | ATZ | 1.0 | IDA | 2.0 | SHS | 1.0 | HMTA | 1.0 | NaOH | 2.0 | — | — | 74.0 |
| CEX1 | 20 | ATZ | 1.0 | IDA | 2.0 | SHS | 1.0 | — | — | — | — | — | — | 77.0 |
| CEX2 | 20 | ATZ | 1.0 | IDA | 2.0 | SHS | 1.0 | — | — | NaOH | 1.0 | — | — | 76.0 |
| CEX3 | 20 | ATZ | 1.0 | IDA | 2.0 | SHS | 1.0 | — | — | — | — | ABF | 0.1 | 75.9 |

PEM1~PEM4: First through fourth present embodiments
CEX1~CEX3: First through third comparative examples
ATZ: 5-aminotetrazole
IDA: Iminodiacetic acid
SHS: Sodium hydrogen sulfate
MEA: Monoethanolamine
HMTA: Hexamethylentetramine
ABF: Ammonium bifluoride

### Etch Performance Experiment

In order to evaluate effects of the etchant composition according to the present disclosure, a sample plate provided with a pattern is prepared by sequentially forming a molybdenum alloy layer of about 300 Å and a copper layer of about 2500 Å on a glass substrate and performing a photolithography procedure for the copper layer and the molybdenum alloy layer.

Also, the copper layer and the molybdenum alloy layer to be etched by spraying the etchant compositions of the first through fourth embodiments and the first through third examples using a spray equipment (Mini-etcher, Model no.: ME-001). After the etch process, the etch properties of the copper layer and the molybdenum alloy layer are observed using a scanning electron microscope (Model no.: S-4800, Manufacturer: Hitachi, Ltd.).

In order to measure a CD (critical dimension) loss, an over etch is performed for the copper and molybdenum alloy layers during about 30% of a designed etch time. The CD loss means a loss which is caused by etching the copper and molybdenum alloy layers beyond the limitation of an etch error unlike the originally designed etch.

In order to check whether or not the oxide semiconductor is etched, another sample plate provided with a pattern is prepared by sequentially forming an oxide semiconductor layer, a molybdenum alloy layer and a copper layer on the glass substrate and performing a photolithography procedure for the copper and molybdenum alloy layers. Also, an etch process is performed for the sample plate (i.e., the copper layer and the molybdenum alloy layer) by spraying the etchant compositions of the first through fourth embodiments and the first through third examples using the spray equipment. After the etch process, the etched state of the sample plate are observed using the scanning electron microscope. In accordance therewith, the experiment resultants as the following table 2 are obtained.

TABLE 2

| | | Cu/MoTi | MoTi | | |
|---|---|---|---|---|---|
| | Cu/MoTi | Taper | Tail | | InGaZnO |
| | etch bias | angle | length | | etch |
| | (μm, 50% | (°, 50% | (μm, 50% | Mo-alloy | (Å, |
| Items | O/E) | O/E)) | O/E) | residual | 300s etch) |
| First | 0.91 | 46.5 | 0.05 | None | None |
| embodiment | | | | | |
| Second | 0.82 | 49.5 | 0.06 | None | None |
| embodiment | | | | | |
| Third | 0.71 | 47.8 | 0.07 | None | None |
| embodiment | | | | | |
| Fourth | 0.86 | 48.6 | 0.05 | None | None |
| embodiment | | | | | |
| Fifth | 0.76 | 48.5 | 0.06 | None | None |
| embodiment | | | | | |
| First | 0.70 | 48.2 | 0.07 | None | 452 |
| comparative | | | | | |
| example | | | | | |
| Second | 0.95 | 48.7 | 0.05 | None | 384 |
| comparative | | | | | |
| example | | | | | |
| Third | 0.89 | 51.2 | 0.04 | None | 897 |
| comparative | | | | | |
| example | | | | | |

As seen from Table 2, it is clear that the etchant compositions according to first through fifth embodiments of the present disclosure are superior in etch bias, taper angle, tail length and so on and allows not only any molybdenum alloy residual to not be generated, but also the oxide semiconductor (InGaZnO) to not be etched.

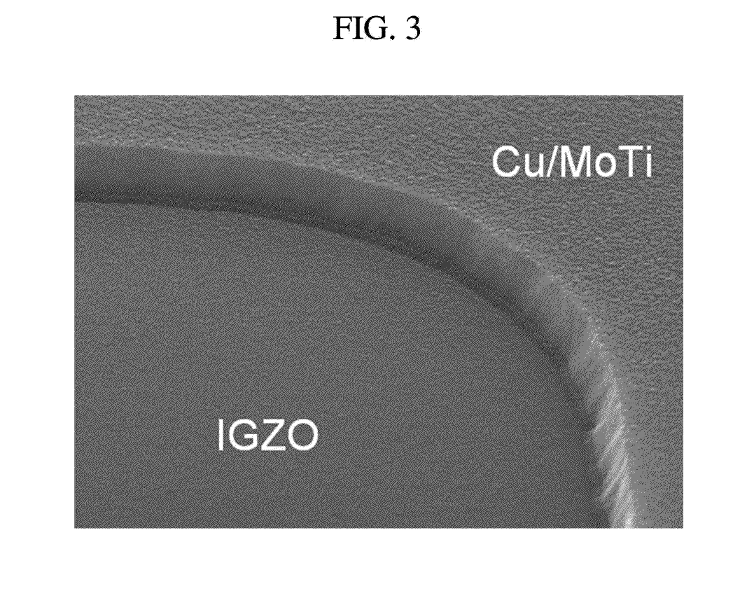

FIGS. 2 and 3 are scanning electron microscope images which show side surfaces (or cross-sections) and a upper surface of the sample plate for checking the thickness variation of an exposed oxide semiconductor (InGaZnO) layer when the copper and molybdenum alloy layers are etched by the etchant composition according to an embodiment of the present disclosure. As seen from FIGS. 2 and 3, it is evident that the copper and molybdenum alloy layers are completely removed, but the oxide semiconductor layer is hardly etched when the etchant composition according to an embodiment of the present disclosure is used.

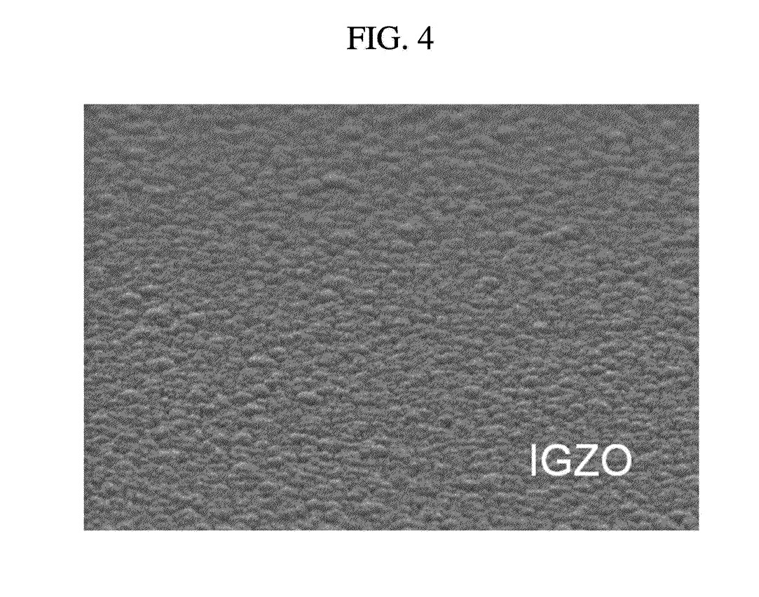

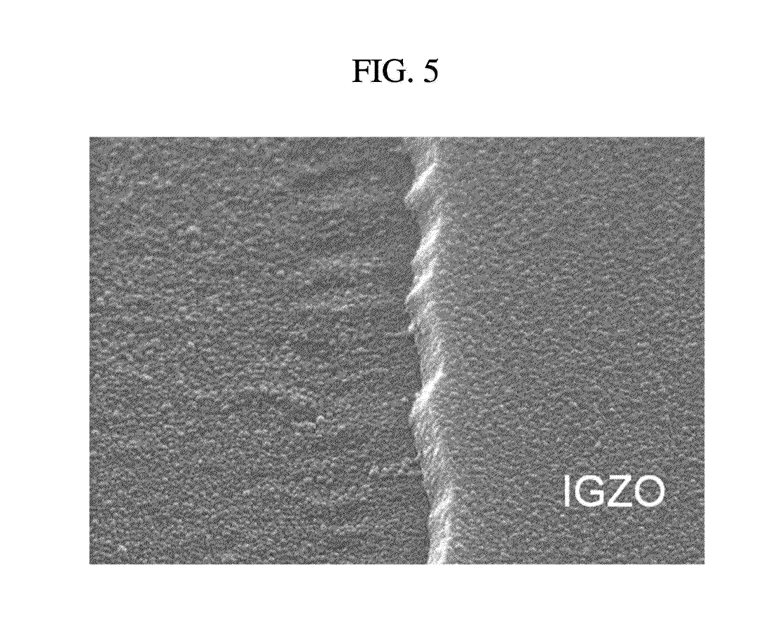

FIG. 4 is a scanning electron microscope image showing a state of an oxide semiconductor layer which is etched by an etchant composition according to an embodiment of the present disclosure. FIG. 5 is a scanning electron microscope image showing a state of an oxide semiconductor layer which is etched by an etchant composition according to a comparative example. In comparison of FIGS. 4 and 5, it is clear that the etch degree of the oxide semiconductor layer by the etchant composition of the comparative example becomes larger than that of the oxide semiconductor layer by the etchant composition according to an embodiment of the present disclosure.

The above-mentioned resultants represent that the etch of the oxide semiconductor layer under copper and molybdenum layers or the copper and molybdenum alloy layers, which are used as an electrode of a display device, is minimized when the copper and molybdenum layers or the copper and molybdenum alloy layers are etched by the etchant composition of the present disclosure. As such, faults of the oxide semiconductor layer can be minimized or prevented.

The etchant composition according to the present disclosure can prevent any etch of the oxide semiconductor layer during a wet etch process of the copper and molybdenum alloy layers. Therefore, faults being easily generated in the etch process can be minimized or prevented.

Although the present disclosure has been limitedly explained regarding only the embodiments described above, it should be understood by the ordinary skilled person in the art that the present disclosure is not limited to these embodiments, but rather that various changes or modifications thereof are possible without departing from the spirit of the present disclosure. More particularly, various variations and modifications are possible in the component parts which are described in the embodiments. Accordingly, the scope of the present disclosure shall be determined only by the appended claims and their equivalents without being limited to the detailed description.

What is claimed is:

1. An etchant composition comprising:
hydrogen peroxide;
an etch inhibitor;
a chelating agent;
an etch additive;
an oxide semiconductor protective agent; and
a pH regulator,
wherein the oxide semiconductor protective agent is included in the etchant composition by about 0.1˜3.0 wt % based on a total weight of the etchant composition.

2. The etchant composition of claim 1, wherein the etch inhibitor is a heterocyclic compound having a carbon number of 1˜10, and includes at least one heteroatom selected from oxygen, sulfur and nitrogen.

3. The etchant composition of claim 1, wherein the chelating agent is a compound which includes all of an amino group and a carboxyl group.

4. The etchant composition of claim 1, wherein the etch additive is one of a compound including an organic acid, an inorganic acid, nitrogen and sulfur, and another compound including an organic acid salt, an inorganic acid salt, nitrogen and sulfur.

5. The etchant composition of claim 1, wherein the oxide semiconductor protective agent is a compound including an amine group.

6. The etchant composition of claim 1, wherein the pH regulator includes at least one of sodium carbonate, sodium hydroxide, potassium hydroxide and ammonia.

7. The etchant composition of claim 1, wherein the pH regulator has a pH value of about 3.5˜6.

8. The etchant composition of claim 1, further comprising water,
wherein when the total weight of the etchant composition is 100 wt %,
the hydrogen peroxide is included by about 5˜40 wt %;
the etch inhibitor is included by about 0.1˜5 wt %;
the chelating agent is included by about 0.1˜5 wt %;
the etch additive is included by about 0.1˜5 wt %;
the oxide semiconductor protective agent is included by about 0.1˜3 wt %;
the pH regulator is included by about 0.1˜3 wt %; and
the water is included by a quantity corresponding to a remaining wt % of the total weight.

9. A method of fabricating a thin film transistor array substrate, the method comprising:
forming a gate electrode on a substrate;
forming a gate insulation film on the substrate provided with the gate electrode;
forming a semiconductor layer on the gate insulation film using an oxide semiconductor material; and
forming a source electrode and a drain electrode on the semiconductor layer,
wherein the source electrode and the drain electrode are formed in a double-layered structure which includes a first electrode material layer and a second electrode material layer disposed on the first electrode material layer.

10. The method of claim 9, wherein the semiconductor layer consists of one of IGZO (indium gallium zinc oxide), IZO (indium zinc oxide), IGO (indium gallium oxide), In₂O₃ and combinations thereof.

11. The method of claim 9, wherein the first electrode material layer consists of a molybdenum alloy and the second electrode material layer is formed from copper.

12. The method of claim 9, wherein the formation of the source and drain electrodes includes:
forming the first electrode material layer on the substrate provided with the semiconductor layer;
forming the second electrode material layer on the first electrode material layer; and
etching the first electrode material layer and the second electrode material layer using an etchant composition.

13. The method of claim 12,
wherein the etchant composition includes hydrogen peroxide, an etch inhibitor, a chelating agent, an etch additive, an oxide semiconductor protective agent, and a pH regulator, and
wherein the oxide semiconductor protective agent is included in the etchant composition by about 0.1˜3.0 wt % based on a total weight of the etchant composition.

14. The method of claim 13, wherein the etch inhibitor is a heterocyclic compound having a the carbon number of 1˜10, and includes at least one heteroatom selected from oxygen, sulfur and nitrogen.

15. The method of claim 13, wherein the chelating agent is a compound which includes all of an amino group and a carboxyl group.

16. The method of claim 13, wherein the etch additive is one of a compound including an organic acid, an inorganic acid, nitrogen and sulfur, and another compound including an organic acid salt, an inorganic acid salt, nitrogen and sulfur.

17. The method of claim 13, wherein the oxide semiconductor protective agent is a compound including an amine group.

18. The method of claim 13, wherein the pH regulator includes at least one of sodium carbonate, sodium hydroxide, potassium hydroxide and ammonia.

19. The method of claim 13, wherein the pH regulator of the etchant composition has a pH value of about 3.5˜6.

20. The method of claim 13, wherein the etchant composition further includes water,
when the total weight of the etchant composition is 100 wt %.
